(19) United States
(12) Patent Application Publication
(10) Pub. No.: US 2017/0292187 A1
(43) Pub. Date: Oct. 12, 2017

(54) APPARATUS FOR LAYER CONTROL-BASED SYNTHESIS AND METHOD OF USING THE SAME

(71) Applicant: INDUSTRY-ACADEMIC COOPERATION FOUNDATION, YONSEI UNIVERSITY, Seoul (KR)

(72) Inventors: Jong Souk YEO, Incheon (KR); Jae Hyun HAN, Uiwang-si (KR)

(73) Assignee: INDUSTRY-ACADEMIC COOPERATION FOUNDATION, YONSEI UNIVERSITY, Seoul (KR)

(21) Appl. No.: 15/278,701

(22) Filed: Sep. 28, 2016

(30) Foreign Application Priority Data
Apr. 12, 2016 (KR) 10-2016-0045046

(51) Int. Cl. C23C 16/455; C23C 16/26

(52) U.S. Cl. CPC C23C 16/455; C23C 16/26

(57) ABSTRACT

Disclosed are an apparatus for layer control-based synthesis and a method of using the same.

### CROSS-REFERENCE TO RELATED APPLICATION

This application claims the priority benefit of Korean Patent Application No. 10-2016-0045046, filed on Apr. 12, 2016 in the Korean Intellectual Property Office, the disclosure of which is incorporated herein by reference.

### BACKGROUND OF THE INVENTION

### Field of the Invention

The present disclosure relates to an apparatus for layer control-based synthesis and a method of using the same, and more particularly, to an apparatus for layer control-based synthesis including a multi-heating zone, and a layer control-based synthesis method of using the same.

### Description of the Related Art

Two-dimensional materials (2D materials) are single-layer or half-layer solids, atoms of which form crystal structures. A representative example of these two-dimensional materials is graphene.

Graphene is a single-layer structure wherein carbon atoms form hexagonal structures. Graphene may have a symmetric band structure with respect to a Dirac point. The effective mass of electric charge at the Dirac point is very small, and thus, electric charge mobility of graphene is at least 10 times (up to 1,000 times) that of silicon (Si). In addition, graphene has a very high Fermi velocity.

As methods of synthesizing graphene, there are a chemical exfoliation method, a chemical vapor deposition (CVD) method, and the like. In the case of graphene synthesized using the chemical vapor deposition method, large-area graphenes are substantially, covalently connected to each other. Accordingly, compared to graphene synthesized using the chemical exfoliation method, superior large-area synthesis can be accomplished and improved sheet resistance and transmittance are exhibited.

In addition, when graphene is synthesized using the chemical vapor deposition method, graphene is formed as a monolayer on a most area of a substrate for growth due to self-limiting growth. However, in the case of the monolayer graphene, there is zero band gap, and thus, application thereof to photoelectronic devices is limited.

Meanwhile, in the cases of Bernal stacked bilayer graphene and rhombohedral-stacked trilayer graphene, a band gap is induced. Accordingly, the aforementioned disadvantage can be addressed.

Research and development of various two-dimensional materials with insulating properties or semiconductive characteristics has been conducted. Research into two-dimensional materials has primarily focused on understanding fundamental properties thereof in flake forms thereof and developing large-area growth methods thereof. Recently, technology for staking different two-dimensional materials has been introduced.

Metal dichalcogenides, compounds of a transition metal and a chalcogen, are nanomaterials with a structure similar to graphene. Metal dichalcogenides have a very thin thickness composed of several atoms, thereby being flexible and transparent. In addition, metal dichalcogenides exhibit various electrical characteristics such as semiconductivity, conductivity, and the like.

In particular, semiconductive metal chalcogenides have an electron mobility (cf/V·s) while having suitable band gaps. Accordingly, semiconductive metal chalcogenides can be suitably applied to semiconductor devices such as transistors and can be very usefully applied to future flexible transistors.

Among metal chalcogenides, MoS₂, WS₂, and the like are being most actively studied. They have direct band gaps in a single-layer state, and thus, optical absorption may occur. Accordingly, they can be suitably applied to optical devices such as light sensors and solar cells.

Research into methods of producing nano thin films composed of such metal chalcogenides is actively underway. However, to apply such metal chalcogenide thin films to the aforementioned devices, methods of evenly, continuously synthesizing a large-area thin film, etc. are required.

Meanwhile, when a chemical vapor deposition method is used, it is not easy to control a layer stacking order, and a stacked structure is randomly formed due to interaction between a sacrificial layer and a multilayer nucleation seed. That is, it is difficult to form a two-dimensional multilayer material having three or more layers as a large area.

Accordingly, to produce multilayer graphene, among two-dimensional multilayer materials, monolayer graphene is prepared, and then the prepared monolayer graphene is laminated to produce multilayer graphene (US Patent Laid-Open Publication No. 2012-0225296). However, this method has disadvantages as follows: interlayer contamination may be caused by randomly stacking the monolayer graphene and a laminated structure is randomly formed.

In addition, a method of preparing graphene by removing of a portion of a sacrificial layer is known (Korean Patent No. 2015-0089840). However, when this method is used, the number of graphene layers depends upon the number of initially formed growth layers by chance, thereby making free control of the number of graphene layers difficult.

Therefore, there is a need for a synthesis technology for preparing a laminated multilayer structure as a large area and easily controlling the number of the layers.

### RELATED DOCUMENTS

### Patent Document

U.S. Pat. No. 8,535,553 (Sep. 17, 2013, LARGE-AREA SINGLE- AND FEW-LAYER GRAPHENE ON ARBITRARY SUBSTRATES)
US Patent Laid-Open Publication No. 2012-0225296 (Sep. 6, 2012, UNIFORM MULTILAYER GRAPHENE BY CHEMICAL VAPOR DEPOSITION)
Korean Patent No. 2015-0089840 (Aug. 5, 2015, Method of forming graphene structure)
Korean Patent No. 2012-0108748 (Oct. 5, 2012, DEVICE FOR PRODUCING GRAPHENE AND METHOD OF PRODUCING GRAPHENE USING THE SAME)
Korean Patent No. 2012-0012271 (Feb. 9, 2012, METHOD OF PRODUCING GRAPHENE, GRAPHENE SHEET, AND DEVICE USING THE GRAPHENE SHEET)

### SUMMARY OF THE INVENTION

Therefore, the present invention has been made in view of the above problems, and it is an object of the present invention to provide an apparatus for layer control-based synthesis for easily controlling of the number of layers of a composite structure, and a method of using the same.

It is another object of the present invention to provide an apparatus for layer control-based synthesis for synthesizing a multilayer, a stacked structure of which is controlled by van der Waals epitaxial growth, and a method of using the same.

It is yet another object of the present invention to provide an apparatus for layer control-based synthesis for economically, massively producing the composite structure as a large area, and a method of using the same.

In accordance with the present invention, the above and other objects can be accomplished by the provision of an apparatus for layer control-based synthesis, including: a first heating zone in which a monolayer of a first material is synthesized; and a second heating zone which is distinguished from the first heating zone and supplies an activated source gas of a second material to the first heating zone, wherein the activated source gas of the second material is nucleated on the monolayer of the first material, and thus, a composite structure is formed.

The first and second materials may be the same two-dimensional materials, and the composite structure may include a multilayer structure wherein the number of homoepitaxially grown layers is controlled.

The multilayer structure may include a Bernal stacked structure.

The first and second materials may be the same two-dimensional materials, and a two-dimensional multilayer material may be synthesized on the monolayer of the first heating zone through repeated van der Waals epitaxial growth based on the activated source gas of the two-dimensional material of the second heating zone having a temperature environment relatively higher than the first heating zone.

The first and second materials may be graphene, and a multilayer graphene may be synthesized in the first heating zone by controlling synthesis time in a temperature environment of 700° C. to 900° C. of the first heating zone and a temperature environment of 1,000° C. to 1,200° C. of the second heating zone.

The first and second materials may be different two-dimensional materials, and the composite structure may include a multilayer structure wherein the number of heteroepitaxially grown layers is controlled.

The first material may be a two-dimensional material, the second material may be a three-dimensional material, and the composite structure includes a hybrid structure wherein the number of layers is controlled.

The second heating zone may include a gas line for supplying the activated source gas of the second material to the first heating zone, and a heating device for heating the gas line such that the gas line has a specific temperature environment.

In accordance with an aspect of the present invention, the above and other objects can be accomplished by the provision of an apparatus for layer control-based synthesis, including: a growth chamber in which a plurality of activated material sources are sequentially synthesized; and a plurality of heating zones which separately supply the activated material sources in different temperature environments to the growth chamber, wherein the activated material sources are sequentially supplied from each of the heating zones to the growth chamber and nucleated in the growth chamber, whereby a composite structure based on the materials is formed.

The heating zones may supply the activated material sources, as the same two-dimensional materials, to the growth chamber, and the composite structure may include a multilayer structure wherein the number of homoepitaxially grown layers is controlled.

The heating zones may supply each of the activated material sources, as different two-dimensional materials, to the growth chamber, and the composite structure may include a multilayer structure wherein the number of heteroepitaxially grown layers is controlled.

The heating zones may supply a plurality of activated material sources respectively different from any one selected from two-dimensional and three-dimensional materials to the growth chamber, and the composite structure may include a hybrid structure wherein the number of layers is controlled.

The heating zones may be disposed with respect to the growth chamber.

In accordance with another aspect of the present invention, there is provided an apparatus for layer control-based synthesis, including: a synthesis unit including a composite heating zone that has a chamber in which a monolayer material is synthesized; and a source heating zone that is distinguished from the composite heating zone and supplies an activated source gas of the material to the chamber such that the activated source gas is nucleated on the monolayer and, accordingly, a composite structure is formed; and a rotator including a stage, in which the composite structure is formed, and providing rotational force to the stage such that the stage is inserted and retracted from the chamber, wherein at least one synthesis unit is disposed with respect to the rotator.

The rotator may enable the stage to be respectively inserted and retracted from the chamber of the at least one synthesis unit such that monolayers are sequentially formed.

In accordance with yet another aspect of the present invention, there is provided a layer control-based synthesis method, the method including: synthesizing a monolayer of a first material in a first heating zone; and supplying an activated source gas of a second material in a second heating zone distinguished from the first heating zone to the first heating zone such that the activated source gas of the second material is nucleated on the monolayer and, accordingly, a composite structure is formed.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates the configuration of an apparatus for layer control-based synthesis according to an embodiment of the present disclosure;

FIG. 2 illustrates a composite structure having a homoepitaxially grown multi-layer structure synthesized by means of an apparatus for layer control-based synthesis according to an embodiment of the present disclosure;

FIGS. 3A and 3B respectively illustrate a perspective view and a plan view of a composite structure with a Bernal stacked structure synthesized by means of an apparatus for layer control-based synthesis of the present disclosure;

FIG. 4 illustrates a graph representing temperature change per synthesis step, upon the synthesis of multilayer graphene according to an embodiment of the present disclosure;

FIGS. 5A to 5E are schematic diagrams of respective steps of a process of synthesizing multilayer graphene by means of an apparatus for layer control-based synthesis according to an embodiment of the present disclosure, along with an optical microscopic (OM) image of graphene transferred onto a SiO₂/Si substrate;

FIG. 6 illustrates a composite structure having a heteroepitaxially grown multilayer structure synthesized by means of an apparatus for layer control-based synthesis according to an embodiment of the present disclosure;

FIG. 7 illustrates a composite structure having a hybrid structure synthesized by means of an apparatus for layer control-based synthesis according to an embodiment of the present disclosure;

FIG. 8 illustrates the configuration of an apparatus for layer control-based synthesis according to another embodiment of the present disclosure;

FIG. 9 illustrates the configuration of an apparatus for layer control-based synthesis according to another embodiment of the present disclosure;

FIG. 10 illustrates the configuration of an apparatus for layer control-based synthesis according to yet another embodiment of the present disclosure;

FIG. 11 illustrates the configuration of an apparatus for layer control-based synthesis according to yet another embodiment of the present disclosure;

FIG. 12 illustrates a flowchart to describe a layer control-based synthesis method according to an embodiment of the present disclosure; and

FIG. 13 illustrates High Resolution Transmission Electron Microscopic (HRTEM) images of monolayer to multilayer (seven-layer) graphenes synthesized by varying time according to an embodiment of the present disclosure.

### DETAILED DESCRIPTION OF THE INVENTION

The present invention will now be described more fully with reference to the accompanying drawings and contents disclosed in the drawings. This invention may, however, be embodied in many different forms and should not be construed as limited to the exemplary embodiments set forth herein.

The terminology used in the present disclosure serves the purpose of describing particular embodiments only and is not intended to limit the disclosure. As used in the disclosure and the appended claims, the singular forms “a”, “an” and “the” are intended to include the plural forms as well, unless context clearly indicates otherwise.

It will be further understood that the terms “includes” and/or “including,” when used in this specification, specify the presence of stated features, steps, operations, elements, and/or components, but do not preclude the presence or addition of one or more other features, steps, operations, elements, components, and/or groups thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

Further, as used in the description of the invention and the appended claims, the singular forms “a”, “an” and “the” are intended to include the plural forms as well, unless context clearly indicates otherwise.

Although terms used in the specification are selected from terms generally used in related technical fields, other terms may be used according to technical development and/or due to change, practices, priorities of technicians, etc. Therefore, it should not be understood that terms used below limit the technical spirit of the present invention, and it should be understood that the terms are exemplified to describe embodiments of the present invention.

Also, some of the terms used herein may be arbitrarily chosen by the present applicant. In this case, these terms are defined in detail below. Accordingly, the specific terms used herein should be understood based on the unique meanings thereof and the whole context of the present invention.

In addition, when an element such as a layer, a film, a region, and a constituent is referred to as being “on” another element, the element can be directly on another element or an intervening element can be present.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Meanwhile, in the following description of the present invention, a detailed description of known functions and configurations incorporated herein will be omitted when it may make the subject matter of the present invention unclear.

The terms used in the specification are defined in consideration of functions used in the present invention, and can be changed according to the intent or conventionally used methods of clients, operators, and users. Accordingly, definitions of the terms should be understood on the basis of the entire description of the present specification.

Hereinafter, an apparatus for layer control-based synthesis according to embodiments of the present disclosure is described in more detail with reference to the accompanying drawings.

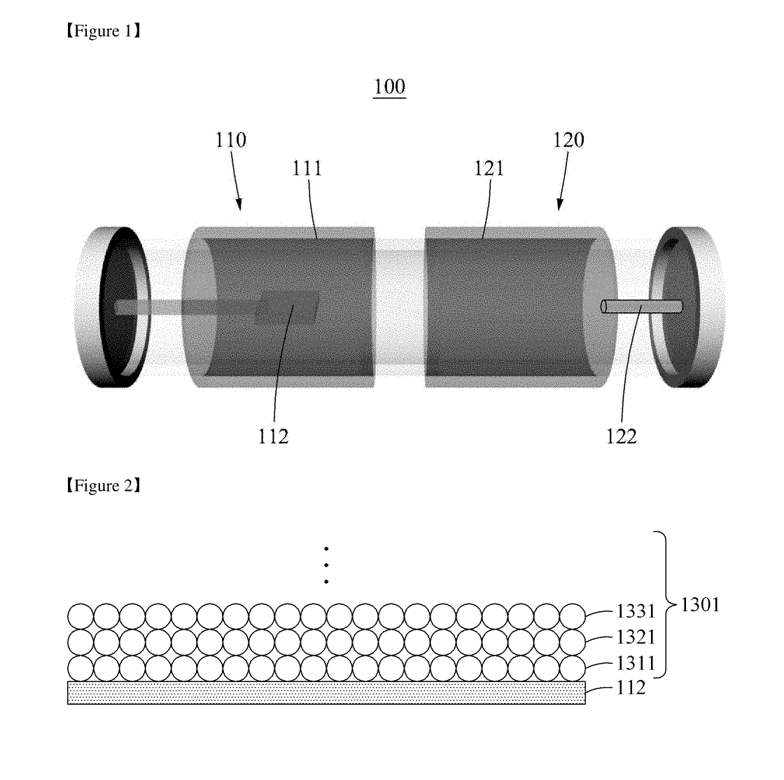

FIG. 1 illustrates the configuration of an apparatus for layer control-based synthesis according to an embodiment of the present disclosure.

An apparatus for layer control-based synthesis according to an embodiment of the present disclosure 100 includes a multi-heating zone which is separated into a first heating zone 100, in which a material is synthesized (grown), and a second heating zone 120, in which source gas of the synthesized material is activated.

The apparatus for layer control-based synthesis according to an embodiment of the present disclosure 100 may be a chemical vapor deposition (CVD)-based device including the multi-heating zone, particularly a low-pressure chemical vapor deposition (LPCVD) device.

With regard to the apparatus for layer control-based synthesis according to an embodiment of the present disclosure 100, the first heating zone 110, in which a material is synthesized, may be a relatively low temperature environment, compared to the second heating zone 120.

Referring to FIG. 1, the apparatus for layer control-based synthesis according to an embodiment of the present disclosure 100 includes the first heating zone 110 and the second heating zone 120, which is distinguished from the first heating zone 110.

In the first heating zone 110, a monolayer of a first material is synthesized. The second heating zone 120, which is distinguished from the first heating zone 110, provides an activated source gas of a second material to the first heating zone 110. In this case, the activated source gas of the second material is nucleated on a monolayer of the first material, thereby forming a composite structure.

In addition, the first heating zone 110 may include a first chamber 111, in which a synthesis process is performed, and a stage 112, in which a material in the first chamber 111 is synthesized (grown).

The first heating zone 110 includes a first heating device (not shown) provided at a side of the first chamber 111, the first heating device heating the first heating zone 110 to create a first temperature environment. The first heating device is not specifically limited and may be any heating device so long as it can heat the first heating zone 110 to create the first temperature environment.

The second heating zone 120 is distinguished from the first heating zone 110, and may include a second chamber 121, in which the activated source gas of the second material is activated, and a gas line 122, which is provided to supply the activated source gas of the second material into the second chamber 121.

In the first heating zone 110 of the apparatus for layer control-based synthesis according to an embodiment of the present disclosure 100, a material is heated. In the second heating zone 120, the source gas of the synthesized material is activated.

In addition, a second temperature environment of the second heating zone 120 may have a relatively high temperature environment, compared to the first temperature environment of the first heating zone 110.

To accomplish this, the second heating zone 120 may include a second heating device (not shown) at a side of the second chamber 121, the second heating device heating the second heating zone 120 to create the second temperature environment. The second heating device is not specifically limited and may be any heating device so long as it can heat the second heating zone 120 to create the second temperature environment

Here, the second temperature environment has a temperature range different from that of the first temperature environment.

The second heating zone 120 of the apparatus for layer control-based synthesis according to an embodiment of the present disclosure 100 heats the source gas of the second material, which is supplied into the second chamber 121 via the gas line 122, to high temperature using the second heating device such that the source gas is activated. The activated source gas of the second material may be supplied to the first heating zone 110.

In addition, with regard to the apparatus for layer control-based synthesis according to an embodiment of the present disclosure 100, the activated source gas of the second material is nucleated on the monolayer of the first material in the first heating zone 110, thereby forming a composite structure.

In particular, the source gas of the second material activated in the second heating zone 120 is supplied into the first heating zone 110 and is nucleated on the monolayer of the first material synthesized on the stage 112 in the first heating zone 110, thereby forming a composite structure.

The second material may be a two-dimensional (2D) or three-dimensional (3D) material, which is the same or different from the first material.

The stage 112 is a base substrate for synthesizing a material. A material of the stage 112 is not specifically limited and may be, for example, an inorganic substance, such as silicon (Si), glass, GaN, or silica, or a metal thin film composed of nickel (Ni), cobalt (Co), iron (Fe), platinum (Pt), gold (Au), aluminum (Al), chrome (Cr), copper (Cu), magnesium (Mg), manganese (Mn), rhodium (Rh), silicon (Si), tantalum (Ta), titanium (Ti), tungsten (W), uranium (U), vanadium (V), zirconium (Zr), or the like.

For example, when graphene is synthesized on the stage 112, the stage 112 may be a metal catalyst such as copper (Cu) foil.

In the first heating zone 110, a monolayer of the first material is synthesized. In particular, the monolayer of the first material is synthesized on the stage 112. The monolayer (unimolecular layer) refers to a layer wherein molecules are arranged in a row, i.e., a thin layer having a thickness corresponding to the size of one molecule.

In addition, the aforementioned two-dimensional material may be any one of graphene based materials, metal dichalcogenides, metal oxides, or metal hydroxides.

The graphene based material may be any one of graphene, hexagonal boron nitride (h-BN), hexagonal boron-nitrogen-carbon (h-BNC), graphene containing fluorine, or graphene oxide (GO).

In addition, the metal dichalcogenide may be a compound of a metal, such as tungsten (W), molybdenum (Mo), or hafnium (Hf), and sulfur (S), selenium (Se), tellurium (Te), or the like.

For example, the metal dichalcogenide may be WS₂, MoS₂, HfS₂, ZrS₂, NbS₂, WSe₂, MoSe₂, HfSe₂, ZrSe₂, NbSe₂, WTe₂, MoTe₂, Hfre₂, ZrTe₂, or NbTe₂.

A transition metal source gas for synthesizing the metal dichalcogenide may include any one transition metal source selected from the group consisting of Ti, Hf, Zr, V, Nb, Ta, Mo, W, Tc, Re, Co, Rh, Ir, Ni, Pd, Pt, Zn, and Sn. A chalcogen source gas for synthesizing the metal dichalcogenide may include any one chalcogen source selected from the group consisting of S, Se, and Te.

In addition, the metal oxide may be any one of MoO₃, WO₃, TiO₂, MnO₂, V₂O₅, TaO₃, RuO₂, LaNb₂O₇, Ca₂Nb₃O₁₀, SrNb₃O₁₀, Bi₄Ti₃O₁₂, and Ca₂Ta₂TiO₁₀.

In addition, the metal hydroxide may be any one of Ni (OH)₂, and Eu (OH)₂.

The three-dimensional material may be any material which can be synthesized by CVD, for example, a conductor, a conductive material such as Cu, Au, Ag, or Pt, a transparent electrode such as ITO, or an oxide semiconductor such as IZO. Examples of the three-dimensional material are not limited to the aforementioned materials and the three-dimensional material may be any material, without specific limitation, so long as the material can be synthesized as a heterostructure with a two-dimensional material.

A composite structure synthesized by means of the apparatus for layer control-based synthesis according to an embodiment of the present disclosure 100 may include a multilayer structure wherein the number of homoepitaxially grown layers can be controlled, when the first and second materials are the same two-dimensional materials.

In accordance with embodiments, the multilayer structure may include a Bernal stacked structure.

In addition, the composite structure synthesized by means of the apparatus for layer control-based synthesis according to an embodiment of the present disclosure 100 may include a multilayer structure wherein the number of heteroepitaxially grown layers may be controlled, when the first and second materials are different two-dimensional materials.

FIG. 2 illustrates a composite structure having a homoepitaxially grown multi-layer structure synthesized by means of an apparatus for layer control-based synthesis according to an embodiment of the present disclosure.

Referring to FIG. 2, a composite structure 1301 synthesized by means of the apparatus for layer control-based synthesis includes a monolayer 1311 of the first material, as a two-dimensional material, and layers 1321 and 1331 of the second material, as a two-dimensional material the same as the first material.

Although the layers of the second material are illustrated as two layers designated as 1321 and 1331, the number of the layers is not limited thereto. In particular, the second material may have at least one layer.

With regard to the composite structure 1301 synthesized by means of the apparatus for layer control-based synthesis, the monolayer 1311 of the first material and the layers 1321 and 1331 of the second material are composed of the same two-dimensional material. Accordingly, the composite structure 1301 may be a multilayer structure homoepitaxially grown from the same material layer.

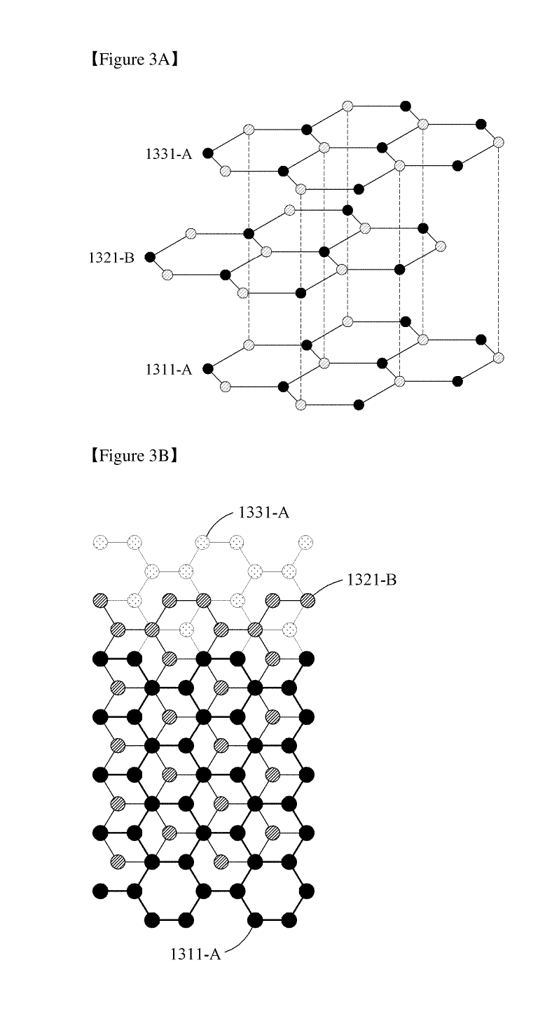

FIGS. 3A and 3B respectively illustrate a perspective view and a plan view of a composite structure with a Bernal stacked structure synthesized by means of an apparatus for layer control-based synthesis of the present disclosure.

Referring to FIGS. 3A and 3B, the multilayer structure 1301 with a composite structure synthesized by means of the apparatus for layer control-based synthesis of the present disclosure may include a Bernal stacked structure.

As illustrated in FIGS. 3A and 3B, the Bernal stacked structure includes a first layer 1321-B of the second material disposed between a monolayer 1311-A of the first material and a second material 1331-A of the second material which are completely overlapped.

With regard to the composite structure 1301 synthesized by means of the apparatus for layer control-based synthesis of the present disclosure, a two-dimensional multilayered material may be synthesized on a monolayer 112 of the first heating zone 110 by repeated van der Waals epitaxial growth based on the activated source gas of the two-dimensional material in the second heating zone 120 having a relatively high temperature environment than the first heating zone 110, when the first and second materials are the same two-dimensional materials.

Hereinafter, the case wherein the first and second materials of the composite structure synthesized by means of the aforementioned apparatus for layer control-based synthesis according to an embodiment of the present disclosure are composed of graphene is described as an embodiment.

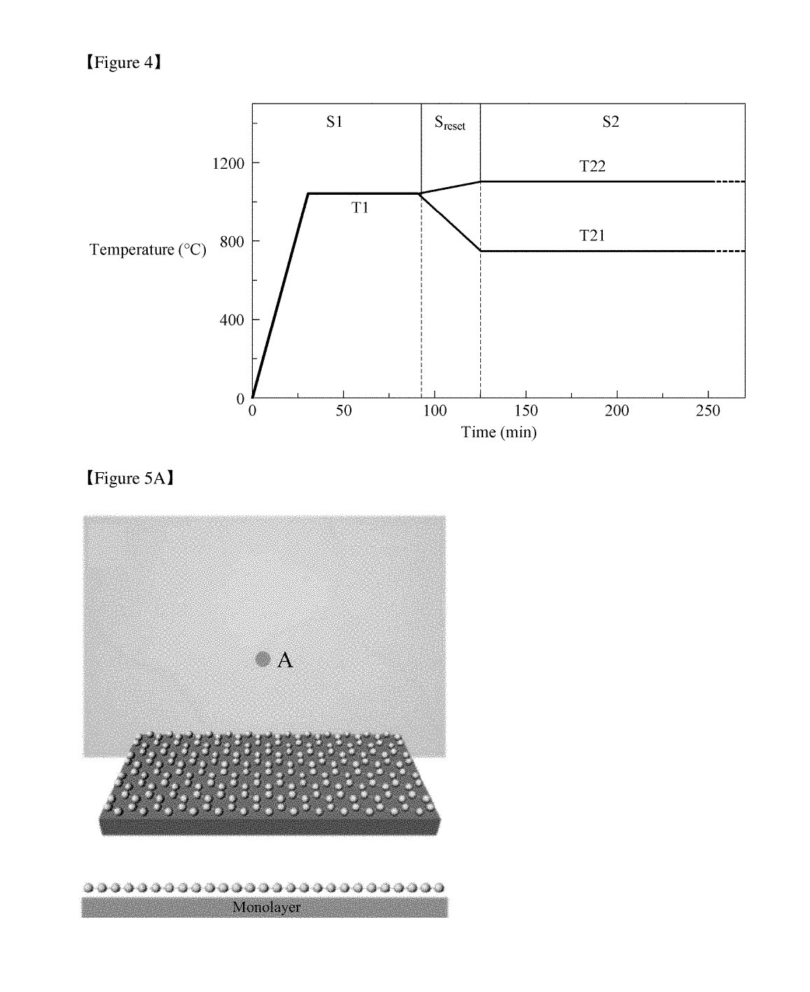

FIG. 4 illustrates a graph representing temperature change per synthesis step, upon the synthesis of multilayer graphene according to an embodiment of the present disclosure.

Using the apparatus for layer control-based synthesis according to an embodiment of the present disclosure 100, the multilayer graphene according to an aspect of the present disclosure may be formed by synthesizing a monolayer graphene on the stage disposed in the first heating zone and then synthesizing graphene through van der Waals epitaxial growth on the monolayer graphene by controlling synthesis time in the first and second heating zones.

Referring to FIG. 4, in step S1, the monolayer graphene is synthesized on the stage disposed in the first heating zone as a temperature of the first heating zone T1 is elevated.

Subsequently, in step S2, a temperature of the first heating zone T21 and a temperature of the second heating zone T22 are respectively controlled to be lower or higher than the temperature of the first heating zone T1 of step S1.

In particular, in step S2, the temperature of the first heating zone T21 is controlled to be relatively low compared to the temperature of the second heating zone T22.

According to an embodiment, a temperature of the second heating zone of step S1 may be the same or different from the temperature of the first heating zone T1.

For example, when the temperature of the first heating zone T1 of step S1 is 900° C. to 1,100° C., the temperature of the first heating zone T21 of step S2 may be 700° C. to 900° C. which is lower than the temperature of the first heating zone T1 of step S1. The temperature of the second heating zone T22 of step S2 may be 1,000° C. to 1,200° C. higher than the temperature of the first heating zone T1 of step S1.

The multilayer graphene 1301 according to an aspect of the present disclosure may be synthesized by controlling synthesis time in the temperature environment of the first heating zone T21, i.e., 700° C. to 900° C., and the temperature environment of the second heating zone T22, i.e., 1,000° C. to 1,200° C.

In particular, the multilayer graphene according to an aspect of the present disclosure may be synthesized as described below with reference to FIG. 1.

In step S2, a carbon gas source for synthesizing graphene may be supplied to the second heating zone 120 via the gas line 122 provided at a side of the second heating zone 120, as illustrated in FIG. 1.

The carbon gas source supplied to the second heating zone 120 is activated due to the relatively high temperature environment of the second heating zone T22, the activated carbon gas source migrates to the first heating zone 110, which has the temperature T21 lower than the temperature of the second heating zone T22, from the second heating zone 120. Accordingly, van der Waals epitaxial growth occurs on the previously synthesized monolayer graphene that is disposed in the first heating zone 110, whereby graphene may be synthesized based on van der Waals epitaxial growth.

In addition, graphene synthesis is repeated based on van der Waals epitaxial growth in step S2 by means of the apparatus for layer control-based synthesis according to an embodiment of the present disclosure, thereby synthesizing multilayer graphene.

In particular, repeated graphene synthesis based on van der Waals epitaxial growth is performed simply by controlling graphene synthesis (growth) time, without other variables, thereby synthesizing the multilayer graphene 1301.

In other words, a layer number of synthesized multilayer graphene may be increased by increasing synthesis time using the apparatus for layer control-based synthesis according to an embodiment of the present disclosure.

The carbon gas source refers to reactive gas including a carbon source for synthesizing the graphene. The carbon source is a carbon-containing compound and types thereof are not specifically limited.

The carbon gas source may be, for example, a C₁ to C₁₀ compound, preferably a C₁ to C₅ compound. For example, the carbon gas source may be a reactive gas including a carbon source that includes methane (CH₄), a carbon number of which is 1, and hydrogen (H₂).

In addition, a temperature environment resetting step Sᵣₑₛₑₜ to control the temperature environments of the first and second heating zones may be further included between steps S1 and S2.

For example, after the monolayer graphene is synthesized for a predetermined time, about 80 minutes, in step S1 and the temperature conditions of the first and second heating zones are reset, the graphene synthesis time in step S2 is controlled, thereby synthesizing a multilayer graphene.

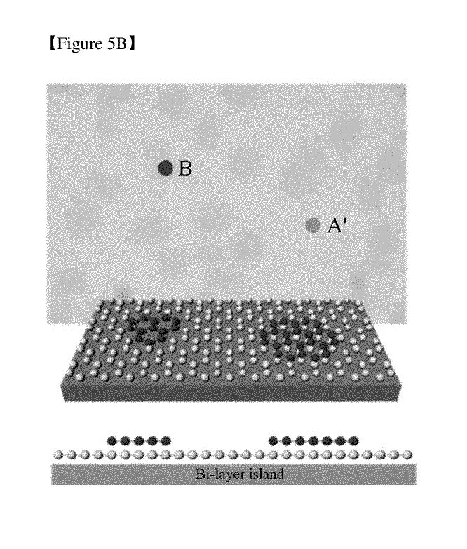

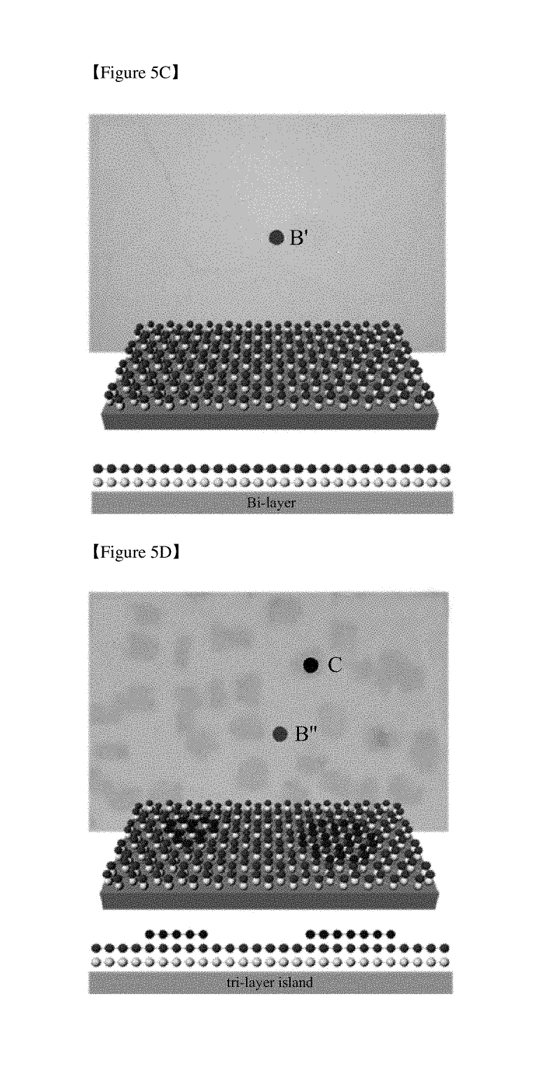

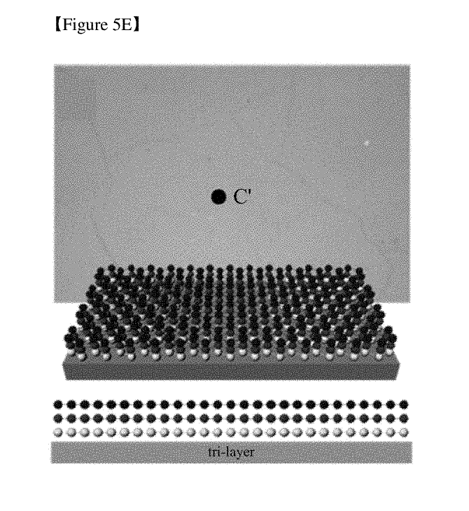

FIGS. 5A to 5E are schematic diagrams of respective steps of a process of synthesizing multilayer graphene by means of an apparatus for layer control-based synthesis according to an embodiment of the present disclosure, along with an optical microscopic (OM) image of graphene transferred onto a SiO₂/Si substrate.

In FIGS. 5A to 5E, spot A and A′ represent monolayer graphene, spots B, B′, and B″ represent bilayer graphene, and spots C and C′ represent trilayer graphene.

FIG. 5A illustrates a schematic diagram of a monolayer graphene synthesized on the copper foil for 10 minutes, as in step S1 of FIG. 4 and an optical microscopic image of the monolayer graphene transferred on a SiO₂/Si substrate. Referring to FIG. 5A, it can be observed that the monolayer graphene is evenly synthesized on the copper foil as a single layer.

FIGS. 5B to 5E illustrate schematic diagrams of graphene respectively synthesized for 20 minutes, 70 minutes, 90 minutes, and 130 minutes, based on van der Waals epitaxial growth, on the monolayer graphene synthesized in step S1, as in step S2 of FIG. 4, and optical microscopic images thereof.

Referring to FIG. 5B, it can be observed that the graphene prepared based on van der Waals epitaxial growth is partially synthesized in island shapes on the monolayer graphene. Referring to FIG. 5C, it can be observed that the graphene based on van der Waals epitaxial growth, which was partially synthesized in island shapes on the monolayer graphene, is synthesized in order to entirely cover the monolayer graphene.

In addition, referring to FIGS. 5D and 5E, it can be observed that graphene based on van der Waals epitaxial growth is partially synthesized on the previously synthesized graphene based on van der Waals epitaxial growth as illustrated in FIG. 5D, and then graphene which was partially synthesized, based on van der Waals epitaxial growth, on the previously synthesized graphene based on van der Waals epitaxial growth is synthesized in order to entirely cover the previously synthesized graphene based on van der Waals epitaxial growth as illustrated in FIG. 5E, in the same manners as in FIGS. 5B and 5C.

Graphene may be repeatedly synthesized layer-by-layer based on van der Waals epitaxial growth by controlling synthesis time by means of the apparatus for layer control-based synthesis according to an embodiment of the present disclosure. In addition, the number of graphene layers based on van der Waals epitaxial growth may be adjusted by controlling synthesis time.

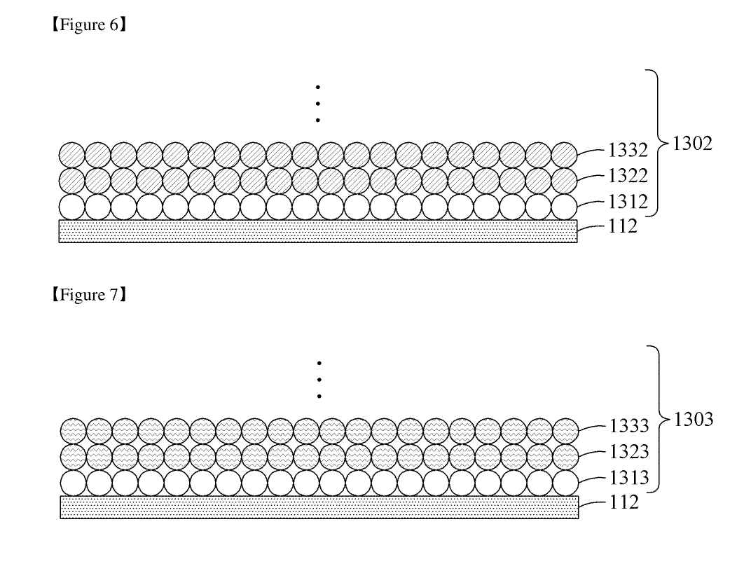

FIG. 6 illustrates a composite structure having a heteroepitaxially grown multilayer structure synthesized by means of an apparatus for layer control-based synthesis according to an embodiment of the present disclosure.

With regard to the apparatus for layer control-based synthesis according to an embodiment of the present disclosure, a composite structure synthesized by means of the apparatus for layer control-based synthesis according to an embodiment of the present disclosure may include a multilayer structure wherein the number of heteroepitaxially grown layers may be controlled, when the first and second materials are different two-dimensional materials.

Referring to FIG. 6, the composite structure synthesized by means of the apparatus for layer control-based synthesis according to an embodiment of the present disclosure may include a monolayer of the first material 1312, as a two-dimensional material, and layers of the second material different from the first material 1322 and 1332, on the stage 112.

For example, when the first material is a two-dimensional material, graphene, as the second material, may be a two-dimensional material, h-BN, different from graphene.

Although the second material illustrated in FIG. 6 is shown as composed of the two layers 1322 and 1332, the number of layers thereof is not specifically limited. In particular, the second material may include at least one layer.

In a composite structure 1302 synthesized by means of the apparatus for layer control-based synthesis according to an embodiment of the present disclosure, the monolayer of the first material 1312 and the layers of the second material 1322 and 1332 are composed of different two-dimensional materials. The composite structure 1302 may be a heteroepitaxially grown multilayer structure grown from different material layers.

In addition, the heteroepitaxially grown multilayer structure 1302 may include the Bernal stacked structure as described above.

FIG. 7 illustrates a composite structure having a hybrid structure synthesized by means of an apparatus for layer control-based synthesis according to an embodiment of the present disclosure.

With regard to the apparatus for layer control-based synthesis according to an embodiment of the present disclosure, a composite structure synthesized by controlling the number of two-dimensional material layers and the thickness of three-dimensional material using the apparatus for layer control-based synthesis according to an embodiment of the present disclosure may include a hybrid structure, the number of layers of which may be controlled, when the first material is a two-dimensional material and the second material is a three-dimensional material.

In addition, the hybrid structure 1303 may include the Bernal stacked structure.

Referring to FIG. 7, the composite structure synthesized by means of the apparatus for layer control-based synthesis according to an embodiment of the present disclosure includes the monolayer 1313 of the first material, as a two-dimensional material, and layers 1323 and 1333 of the second material, as a three-dimensional material, on the stage 112.

For example, when the first material is two-dimensional material such as graphene, the second material may be a three-dimensional material.

The three-dimensional material may be any material which can be synthesized by CVD, for example, a conductor, a conductive material such as Cu, Au, Ag, or Pt, a transparent electrode such as ITO, or an oxide semiconductor such as IZO. Examples of the three-dimensional material are not limited to the aforementioned materials and the three-dimensional material may be any material, without specific limitation, so long as it can be synthesized with a two-dimensional material as a heterostructure.

Although the second material illustrated in FIG. 7 has two layers 1323 and 1333, a layer number thereof is not specifically limited. In particular, the second material may include at least one layer.

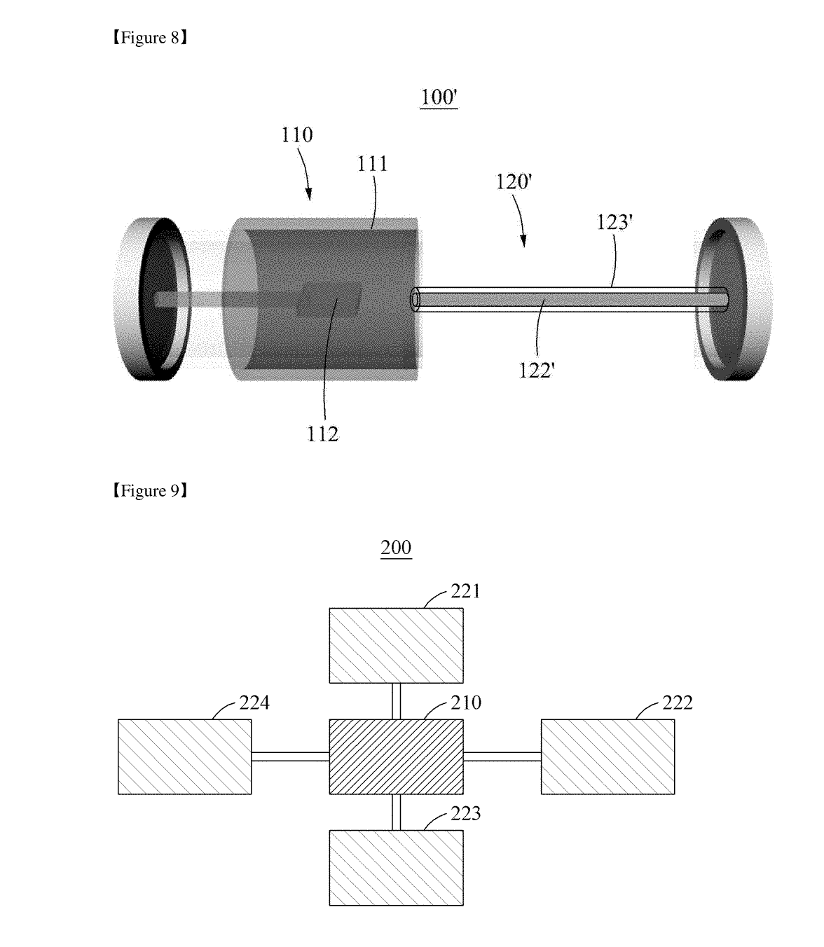

Hereinafter, an apparatus for layer control-based synthesis according to another embodiment of the present disclosure is described in detail with reference to FIG. 8.

FIG. 8 illustrates the configuration of an apparatus for layer control-based synthesis according to another embodiment of the present disclosure.

An apparatus for layer control-based synthesis 100′ according to another embodiment of the present disclosure may include the technical components of the aforementioned apparatus for layer control-based synthesis of the present disclosure. Description of identical components is omitted.

The apparatus for layer control-based synthesis 100′ according to another embodiment of the present disclosure includes a multi-heating zone which is separated into a first heating zone 100, in which a material is synthesized (grown), and a second heating zone 120′, in which source gas of the synthesized material is activated.

In the first heating zone 110, a monolayer of a first material is synthesized. The second heating zone 120′, which is distinguished from the first heating zone 110, provides an activated source gas of a second material to the first heating zone 110. In this case, the activated source gas of the second material is nucleated on a monolayer of the first material, thereby forming a composite structure.

In addition, the first heating zone 110 may include a first chamber 111, in which a synthesis process is performed, and a stage 112, in which a material in the first chamber 111 is synthesized (grown).

The first heating zone 110 includes a first heating device (not shown) provided at a side of the first chamber 111, the first heating device heating the first heating zone 110 to create a first temperature environment. The first heating device is not specifically limited and may be any heating device capable of heating the first heating zone 110 to create the first temperature environment.

As illustrated in FIG. 8, the second heating zone 120′ may include a gas line 122′ for supplying an activated source gas of a second material to the first heating zone 110 and a heating device (second heating device 123′) for heating the gas line 122′ to create a specific temperature environment.

The source gas of the second material of the second heating zone 120′ may be supplied to the gas line 122′, and the gas line 122′ may supply the supplied source gas to the first heating zone 110.

The second heating device 123′ heats the source gas of the second material supplied to the interior of the gas line 122′ under a specific temperature environment, thereby activating the source gas of the second material. That is, the activated source gas of the second material may be supplied to the first heating zone 110 via the gas line 122′ by means of the second heating device 123′.

FIG. 8 illustrates the second heating device 123′ enveloping the gas line 122′. However, the structure of the second heating zone 120′ is not specifically limited so long as the second heating device 123′ is provided to heat the second heating zone 120′ to a specific second temperature environment.

Hereinafter, an apparatus for layer control-based synthesis according to yet another embodiment of the present disclosure is described with reference to FIG. 9.

FIG. 9 illustrates the configuration of an apparatus for layer control-based synthesis according to another embodiment of the present disclosure.

An apparatus for layer control-based synthesis 200 according to another embodiment of the present disclosure may include the technical components of the aforementioned apparatus for layer control-based synthesis of the present disclosure. Descriptions for the same components are omitted.

Referring to FIG. 9, the apparatus for layer control-based synthesis 200 according to yet another embodiment of the present disclosure includes a growth chamber 210, in which a plurality of activated material sources are sequentially synthesized, and a plurality of heating zones 221, 222, 223, and 224 (hereinafter referred to as 220), temperature environments of which are different and which supply the activated material sources to the growth chamber 210.

The material sources activated by means of the apparatus for layer control-based synthesis 200 according to yet another embodiment of the present disclosure are sequentially provided from each of the heating zones 220 to the growth chamber 210 and are nucleated in the growth chamber 210, thereby forming a composite structure based on the materials.

The activated material sources from the heating zones 220 are sequentially supplied to the growth chamber 210, whereby a composite structure based on the materials is formed in the growth chamber 210.

The heating zones 220 may be disposed near the growth chamber 210 with respect to the growth chamber 210.

Although the heating zones 220 are exemplified as the four heating zones 221, 222, 223, and 224 as illustrated in FIG. 9, the number thereof is not specifically limited and may depend upon the number of material sources to be activated.

The heating zones 220 respectively activate the material sources so as to supply the activated material sources to the growth chamber 210.

To activate the material sources according to an example, a heating device (not shown) may be supplied at a side of the heating zones 220. In addition, a source line (not shown) may be supplied at each of the heating zones 220 such that the material sources are supplied to the heating zones 220.

The material sources activated in the heating zones 220 are sequentially supplied from each of the heating zones 220 to the growth chamber 210. The activated material sources supplied to the growth chamber 210 are nucleated in the growth chamber 210, thereby forming a composite structure based on the materials.

By means of the apparatus for layer control-based synthesis 200 according to yet another embodiment of the present disclosure, a plurality of material sources are respectively activated in the heating zones 220 and then supplied to the growth chamber 210, thereby forming a composite structure based on the materials in the growth chamber 210.

The material sources may be the same or different materials. That is, the activated material sources activated in the heating zones 220 may be the same or different materials. The material sources may be two-dimensional materials.

With regard to the apparatus for layer control-based synthesis 200 according to yet another embodiment of the present disclosure, the heating zones 220 may provide the activated material sources, as the same two-dimensional materials, to the growth chamber 210, when the material sources are the same materials.

In this case, the material sources-based composite structure nucleated and synthesized in the growth chamber 210 of the apparatus for layer control-based synthesis 200 according to yet another embodiment of the present disclosure may include a multilayer structure wherein the number of homoepitaxially grown layers may be controlled.

Meanwhile, with regard to the apparatus for layer control-based synthesis 200 according to yet another embodiment of the present disclosure, the heating zones 220 may provide the activated material sources, as different two-dimensional materials, to the growth chamber 210, when the material sources are different materials.

In this case, the material sources-based composite structure nucleated and synthesized in the growth chamber 210 of the apparatus for layer control-based synthesis 200 according to yet another embodiment of the present disclosure may include a multilayer structure wherein the number of heteroepitaxially grown layers may be controlled.

In accordance with an embodiment, the material sources may be three-dimensional materials.

With regard to the apparatus for layer control-based synthesis 200 according to yet another embodiment of the present disclosure, the heating zones 220 may provide the activated material sources, which are selected from two-dimensional and three-dimensional materials and different from each other, to the growth chamber 210, when the material sources are selected from two-dimensional and three-dimensional materials and different from each other.

In this case, the material sources-based composite structure nucleated and synthesized in the growth chamber 210 of the apparatus for layer control-based synthesis 200 according to yet another embodiment of the present disclosure may include a hybrid structure wherein the number and thickness of layers may be controlled.

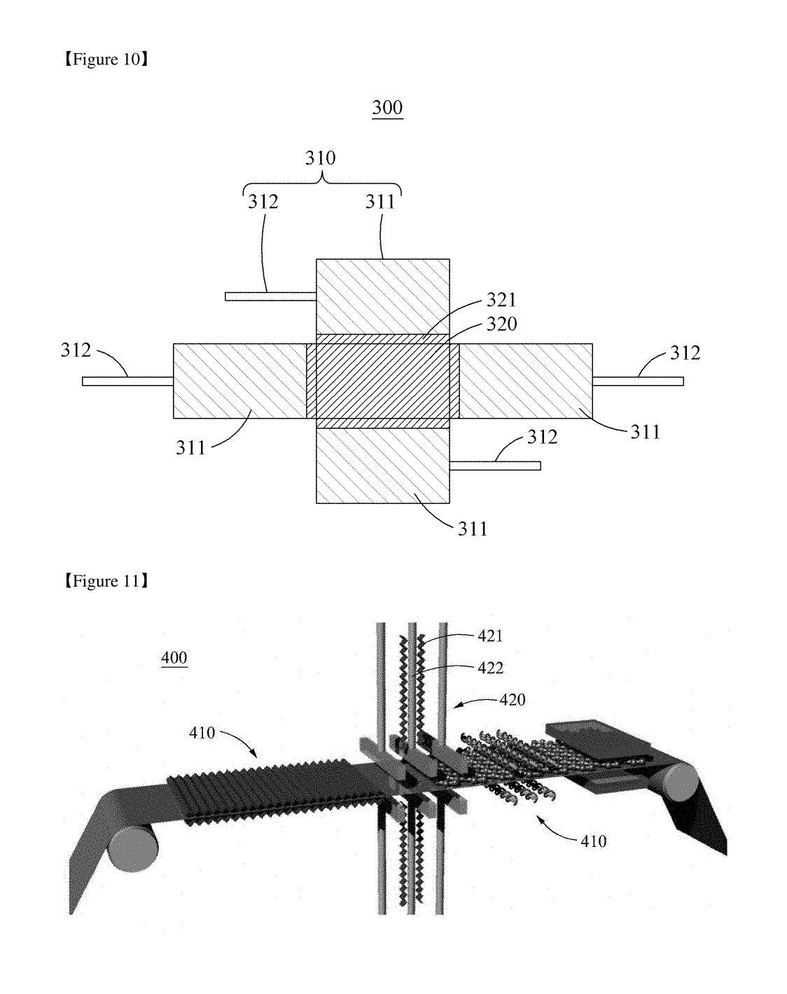

Hereinafter, an apparatus for layer control-based synthesis according to yet another embodiment of the present disclosure is described with reference to FIG. 10.

FIG. 10 illustrates the configuration of an apparatus for layer control-based synthesis according to yet another embodiment of the present disclosure.

An apparatus for layer control-based synthesis 300 according to another embodiment of the present disclosure may include the technical components of the aforementioned apparatus for layer control-based synthesis of the present disclosure. Description of identical components is omitted.

Referring to FIG. 10, an apparatus for layer control-based synthesis 300 according to yet another embodiment of the present disclosure may include synthesis units 310, which include composite heating zones 311 and source heating zones 312, and a rotator 320, which includes stages 321.

The synthesis units 310 include the composite heating zones 311 that include a chamber (not shown) in which a monolayer material is synthesized, and the source heating zones 312 that are distinguished from the composite heating zones 311 and supply the activated source gas of the material to the chamber such that the activated source gas is nucleated on the monolayer and a composite structure is formed.

At least one synthesis unit 310 is disposed with respect to the rotator 320.

The rotator 320 includes the stages 321 in which a composite structure is formed. The rotator 320 provides rotational force to the stages 321 such that the stages 321 are inserted into the chamber and extracted therefrom.

With regard to the apparatus for layer control-based synthesis 300 according to yet another embodiment of the present disclosure, the rotator 320 enables each of the stages 321 to be inserted and retracted from each chamber of the at least one synthesis unit 310 such that monolayers are sequentially formed.

When a composite structure is formed by means of the apparatus for layer control-based synthesis 300 including at least one synthesis unit 310 with respect to the rotator 320 according to yet another embodiment of the present disclosure, cross-contamination may be prevented.

Hereinafter, an apparatus for layer control-based synthesis according to yet another embodiment of the present disclosure is described with reference to FIG. 11.

FIG. 11 illustrates the configuration of an apparatus for layer control-based synthesis according to yet another embodiment of the present disclosure.

An apparatus for layer control-based synthesis 400 according to yet another embodiment of the present disclosure may include the technical components of the aforementioned apparatus for layer control-based synthesis of the present disclosure. Description of identical components is omitted.

Referring to FIG. 11, an apparatus for layer control-based synthesis 400 according to yet another embodiment of the present disclosure is a roll-to-roll type and includes first and second heating zones 410 and 420. The first heating zone 410 has a relatively low temperature environment, compared to the second heating zone 420.

The first heating zone 410 may include a transportation device for synthesis and the first heating device (not shown) provided at a side of the transportation device and performing heating.

The first heating zone 410 is a roll-to-roll type and may provide a monolayer of the first material in a direction of the second heating zone 420.

The second heating zone 420 may include second heating devices 421 for activating the source gas of the second material and gas lines 422 for providing the source gas of the (activated) second material to the monolayer of the first material.

The second heating zone 420 provides the activated source gas of the second material onto the monolayer of the first material provided from the first heating zone 410.

For example, the source gas of the second material may be activated by the second heating devices 421 disposed near the gas lines 422 while being supplied via the gas lines 422.

When a composite structure is formed by means of the roll-to-roll type apparatus for layer control-based synthesis 400 according to yet another embodiment of the present disclosure, the composite structure may be formed in a large area and the number of layers thereof may be controlled.

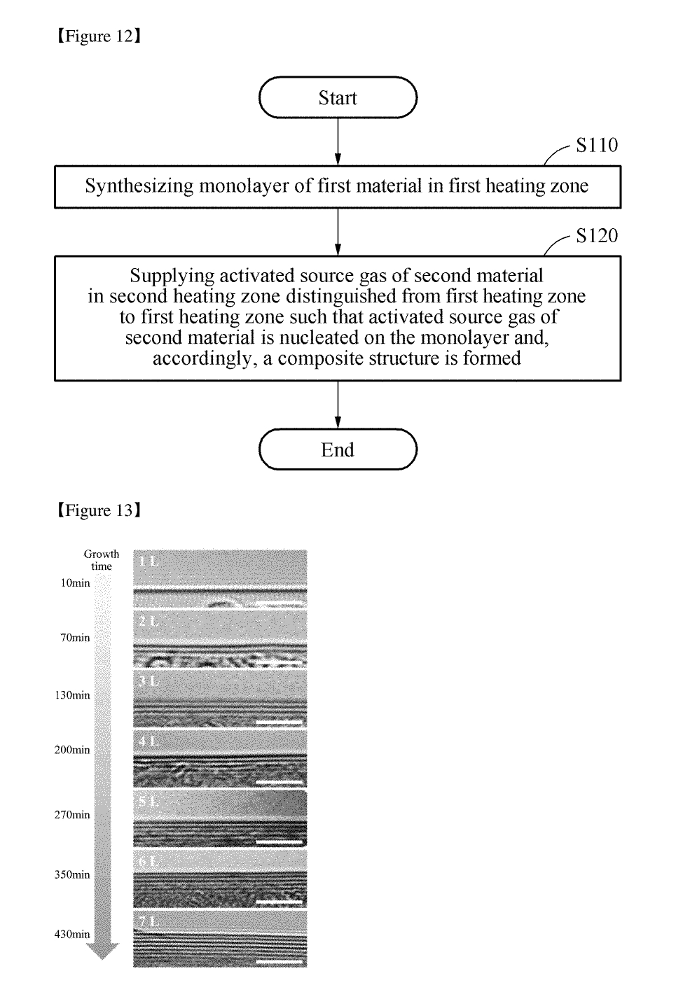

Hereinafter, a layer control-based synthesis method of the present disclosure is described with reference to FIG. 12.

FIG. 12 illustrates a flowchart to describe a layer control-based synthesis method according to an embodiment of the present disclosure.

Referring to FIG. 12, a layer control-based synthesis method according to an embodiment of the present disclosure includes step S110 wherein a monolayer of the first material is synthesized in a first heating zone of an apparatus for layer control-based synthesis.

In addition, in step S120 of the layer control-based synthesis method, the activated source gas of the second material from the second heating zone 120 distinguished from the first heating zone 110 is supplied to the first heating zone 110 and the activated source gas of the second material is nucleated on the monolayer, thereby forming a composite structure.

### Example: Method of Synthesizing Multilayer Graphene Composite Structure

With regard to a composite structure synthesized by means of the apparatus for layer control-based synthesis of the present disclosure, a multilayer graphene may be synthesized as a composite structure by means of an apparatus for layer control-based synthesis according to an embodiment of the present disclosure when the first and second materials are the same graphene materials.

According to an aspect of the present disclosure, the multilayer graphene was synthesized by repeating graphene synthesis based on van der Waals epitaxial growth through control of only graphene synthesis (growth) time, without other variables, as illustrated in FIGS. 4 to 5E.

In particular, to synthesize monolayer graphene, a chemically-mechanically polished (CMP) copper foil with a thickness of about 25 μm, as a based substrate for synthesizing graphene, was first disposed in the middle of a first heating zone.

The temperatures of the first heating zone and a second heating zone were elevated up to 1,040° C. over about 40 minutes and the elevated temperatures were maintained for about 40 minutes, thereby synthesizing a large-area monolayer graphene on the copper foil base substrate. Here, a condition of the synthesis was as follows: 10 sccm of CH₄ gas and 300 sccm of H₂ gas were introduced into the first and second heating zones at 1 Torr and 1,040° C. for about 10 minutes.

The previously synthesized monolayer graphene was used as a substrate to synthesize graphene based on van der Waals epitaxial growth.

In particular, to synthesize graphene based on van der Waals epitaxial growth, the flux of CH₄ gas was adjusted to 100 sccm, the flux of H₂ gas was adjusted to 10 sccm, an internal pressure of a chamber was adjusted to 1 Torr, the temperature of the first heating zone was set to 750° C., and the temperature of the second heating zone was set to 1,100° C., such that graphene synthesis based on van der Waals epitaxial growth was performed on the previously synthesized monolayer graphene.

As a result, a multilayer graphene, which was formed by graphene synthesis based on van der Waals epitaxial growth, was synthesized on the monolayer graphene.

FIG. 13 illustrates High Resolution Transmission Electron Microscopic (HRTEM) images of monolayer to multilayer (seven-layer) graphenes synthesized by varying time according to an embodiment of the present disclosure.

Referring to FIG. 13, it can be observed that graphene may be synthesized as various layers by controlling graphene synthesis time from 10 minutes up to 430 minutes. In particular, it can be confirmed that monolayer graphene is synthesized when a graphene synthesis (growth) time is 10 minutes, two-layer graphene is synthesized when the time is 70 minutes, three-layer graphene is synthesized when the time is 130 minutes, four-layer graphene is synthesized when the time is 200 minutes, five-layer graphene is synthesized when the time is 270 minutes, six-layer graphene is synthesized when the time is 350 minutes, and seven-layer graphene is synthesized when the time is 430 minutes.

As described above, a layer number of the composite structure synthesized using the apparatus for layer control-based synthesis and the method of using the same according to an embodiment of the present disclosure can be easily controlled.

In addition, by using the apparatus for layer control-based synthesis and the method of using the same according to an embodiment of the present disclosure, a multilayer, a laminated structure of which is controlled through van der Waals epitaxial growth, can be synthesized.

Further, by using the apparatus for layer control-based synthesis and the method of using the same according to an embodiment of the present disclosure, a large-area composite structure can be economically mass-produced.

Although the present invention has been described through limited examples and figures, the present invention is not intended to be limited to the examples. Those skilled in the art will appreciate that various modifications, additions and substitutions are possible, without departing from the scope and spirit of the invention.

It should be understood, however, that there is no intent to limit the invention to the embodiments disclosed, rather, the invention is to cover all modifications, equivalents, and alternatives falling within the spirit and scope of the invention as defined by the claims.

### DESCRIPTION OF SYMBOLS

100, 100′, 200, 300, 400: APPARATUS FOR LAYER CONTROL-BASED SYNTHESIS
110, 410: FIRST HEATING ZONE
111: FIRST CHAMBER
112, 321: STAGE
120, 120′, 420: SECOND HEATING ZONE
121: SECOND CHAMBER
122, 122′, 422: GAS LINE
123′, 421: SECOND HEATING DEVICE
1301, 1302, 1303: COMPOSITE STRUCTURE
1311, 1312, 1313: MONOLAYER OF FIRST MATERIAL
1321, 1331, 1322, 1332, 1323, 1333: LAYER OF SECOND MATERIAL
210: GROWTH CHAMBER
221, 222, 223, 224: HEATING ZONE
310: SYNTHESIS UNIT
311: COMPOSITE HEATING ZONE
312: SOURCE HEATING ZONE
320: ROTATOR

What is claimed is:

1. An apparatus for layer control-based synthesis, comprising:
a first heating zone in which a monolayer of a first material is synthesized; and
a second heating zone which is distinguished from the first heating zone and supplies an activated source gas of a second material to the first heating zone,
wherein the activated source gas of the second material is nucleated on the monolayer of the first material, and thus, a composite structure is formed.

2. The apparatus according to claim 1, wherein the first and second materials are the same two-dimensional materials, and
the composite structure comprises a multilayer structure wherein the number of homoepitaxially grown layers is controlled.

3. The apparatus according to claim 2, wherein the multilayer structure comprises a Bernal stacked structure.

4. The apparatus according to claim 2, wherein the first and second materials are the same two-dimensional materials, and
a two-dimensional multilayer material is synthesized on the monolayer of the first heating zone through repeated van der Waals epitaxial growth based on the activated source gas of the two-dimensional material of the second heating zone having a temperature environment relatively higher than the first heating zone.

5. The apparatus according to claim 4, wherein the first and second materials are graphene, and
a multilayer graphene is synthesized in the first heating zone by controlling synthesis time in a temperature environment of 700° C. to 900° C. of the first heating zone and a temperature environment of 1,000° C. to 1,200° C. of the second heating zone.

6. The apparatus according to claim 1, wherein the first and second materials are different two-dimensional materials, and
the composite structure comprises a multilayer structure wherein the number of heteroepitaxially grown layers is controlled.

7. The apparatus according to claim 1, wherein the first material is a two-dimensional material,
the second material is a three-dimensional material, and
the composite structure comprises a hybrid structure wherein the number of layers is controlled.

8. The apparatus according to claim 1, wherein the second heating zone comprises a gas line for supplying the activated source gas of the second material to the first heating zone, and a heating device for heating the gas line such that the gas line has a specific temperature environment.

9. An apparatus for layer control-based synthesis, comprising:
a growth chamber in which a plurality of activated material sources are sequentially synthesized; and
a plurality of heating zones which separately supply the activated material sources in different temperature environments to the growth chamber,
wherein the activated material sources are sequentially supplied from each of the heating zones to the growth chamber and nucleated in the growth chamber, whereby a composite structure based on the materials is formed.

10. The apparatus according to claim 9, wherein the heating zones supply the activated material sources, as the same two-dimensional materials, to the growth chamber, and
the composite structure comprises a multilayer structure wherein the number of homoepitaxially grown layers is controlled.

11. The apparatus according to claim 9, wherein the heating zones supply each of the activated material sources, as different two-dimensional materials, to the growth chamber, and
the composite structure comprises a multilayer structure wherein the number of heteroepitaxially grown layers is controlled.

12. The apparatus according to claim 9, wherein the heating zones supply a plurality of activated material sources respectively different from any one selected from two-dimensional and three-dimensional materials to the growth chamber, and
the composite structure comprises a hybrid structure wherein the number of layers is controlled.

13. The apparatus according to claim 9, wherein the heating zones are disposed with respect to the growth chamber.

14. An apparatus for layer control-based synthesis, comprising:
a synthesis unit comprising a composite heating zone that has a chamber in which a monolayer material is synthesized; and a source heating zone that is distinguished from the composite heating zone and supplies an activated source gas of the material to the chamber such that the activated source gas is nucleated on the monolayer and, accordingly, a composite structure is formed; and
a rotator comprising a stage, in which the composite structure is formed, and providing rotational force to the stage such that the stage is inserted and retracted from the chamber,
wherein at least one synthesis unit is disposed with respect to the rotator.

15. The apparatus according to claim 14, wherein the rotator enables the stage to be respectively inserted and retracted from the chamber of the at least one synthesis unit such that monolayers are sequentially formed.

16. A layer control-based synthesis method, the method comprising:
synthesizing a monolayer of a first material in a first heating zone; and
supplying an activated source gas of a second material in a second heating zone distinguished from the first heating zone to the first heating zone such that the activated source gas of the second material is nucleated on the monolayer and, accordingly, a composite structure is formed.
